(19) United States
(12) Patent Application Publication
(10) Pub. No.: US 2026/0150586 A1
(43) Pub. Date: May 28, 2026

(54) HALL EFFECT SENSOR AND INTEGRATED CIRCUIT WITH DISTRIBUTED SENSING AND BIAS ELECTRODES

(71) Applicant: CIRRUS LOGIC INTERNATIONAL SEMICONDUCTOR LTD., Edinburgh (GB)

(72) Inventors: Donelson A. Shannon, Austin, TX (US); Marcus W. May, Austin, TX (US); Eric B. Smith, Austin, TX (US); Mikel Ash, Austin, TX (US); John L. Melanson, Austin, TX (US)

(21) Appl. No.: 18/956,867

(22) Filed: Nov. 22, 2024

(51) Int. Cl. H10N 52/00; G01R 33/07; H10N 52/80

(52) U.S. Cl. CPC H10N 52/101; G01R 33/075; H10N 52/80

(57) ABSTRACT

A Hall effect sensor device provides improved sensitivity and allows for electrode rotation, i.e., “spinning” in an asymmetric sense/bias configuration. The Hall effect sensor device includes a semiconductor magnetic field sensing element body integrated on a die, multiple bias electrodes disposed on and in electrical contact with the semiconductor magnetic field sensing element, with at least two bias electrodes corresponding to and disposed on each side of the sensing element body. The Hall effect sensor also includes multiple sensing electrodes separate from the bias electrodes, with at least one sensing conductor corresponding to each side of the sensor body, so that each of the sensing electrodes sense voltage across the semiconductor magnetic field sensing element body and never conduct a bias current.

### BACKGROUND

### 1. Field of Disclosure

The field of representative embodiments of this disclosure relates to Hall Effect sensor circuits, and in particular to a Hall effect sensor having distributed sensing and bias electrodes.

### 2. Background

Hall effect sensors and other semiconductor magnetic field sensors are widely used in applications in which it is desirable to provide a measurement of DC magnetic fields and relatively low frequency AC magnetic fields that are not otherwise easily sensed with coils or other antennas. Such applications include position and motion sensors for both linear and rotational motion, power supply and motor control applications in which the transformer or motor fields are detected, audio speaker applications in which the strength of the speaker's signal-induced field is detected, and lighting controllers for high-frequency energized lamps, such as sodium lamps.

Hall effect sensors operate by providing a layer of semiconductor material with a bias current applied across one axis and sensing a voltage across the other axis. When a magnetic field is present, the uniformity of the current in the layer of material is distorted, causing non-uniform voltage distribution along the material and a differential voltage to appear across a pair of sensing electrodes. To improve performance, the electrodes receiving the bias current can be rotated by interchanging them with the electrodes used to sense the output voltage by using a switching network, effectively rotating or “spinning” the position of the electrodes. Offset and noise in the resulting output signal is modulated to a higher carrier frequency, which can then be easily filtered from the magnetic field measurement component, improving the accuracy of the magnetic field measurement. The spinning also aids in averaging out any variations in the semiconductor material.

The structure of the electrodes in a Hall effect sensor has an impact on the sensitivity of the sensor. Since the bias is applied across the body of the sensor in one axis, and the sensor output voltage is sensed across an orthogonal axis, the conductive material forming the electrodes distorts the electric field along their length due to current conduction in the electrodes, reducing the sensor output voltage. To reduce the field distortion, cross-shaped sensor bodies have been implemented that remove the electrodes from the central area of the sensor body and finger-shaped extensions of the electrodes, such as those disclosed in U.S. Pat. No. 10,353,017 have been included using multiple electrodes on each sensor side, reducing the conduction of currents that reduce the sensor output voltage by breaking up the potential current conduction paths along the electrodes, while maintaining the sensor symmetry that is required for spinning the electrodes. However, as the electrodes are separate from the main sensor body, and are reduced in area, application of the bias current is affected, reducing the amount of current that may be practically introduced.

Therefore, it would be desirable to provide a semiconductor magnetic field sensor that has improved sensitivity, while including rotation/spinning to remove noise and offset.

### SUMMARY

Improved sensitivity in a Hall effect sensor is achieved in sensors, integrated circuits (ICs) including the sensors, and their methods of operation.

The Hall effect sensors include a semiconductor magnetic field sensing element body integrated on a die and having multiple sides, multiple of bias electrodes disposed on and in electrical contact with the semiconductor magnetic field sensing element, with at least two of the bias electrodes corresponding to and disposed on each side, and multiple sensing electrodes separate from the bias electrodes and including at least one sensing conductor corresponding to each side, so that each of the sensing electrodes sense voltage across the semiconductor magnetic field sensing element body and never conduct a bias current.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1 is a block diagram illustrating an example system 10, in accordance with an embodiment of the disclosure.

FIG. 2 is a block diagram illustrating an example circuit 22 that may be used to implement Hall effect sensor 12 and switching circuits 14A, 14B in example system 10, in accordance with another embodiment of the disclosure.

FIG. 3A is a perspective view of an example integrated circuit (IC) 30A that may be used to implement system 10 of FIG. 1, in accordance with an embodiment of the disclosure.

FIG. 3B is a top view of example integrated circuit (IC) 30A of FIG. 3A, in accordance with an embodiment of the disclosure.

FIG. 4A is a perspective view of another example integrated circuit (IC) 40A that may be used to implement system 10 of FIG. 1, in accordance with another embodiment of the disclosure.

FIG. 4B is a top view of example integrated circuit (IC) 40A of FIG. 4A, in accordance with an embodiment of the disclosure.

FIG. 5 is a simplified schematic diagram showing details of an example sensing circuit 16A and interface circuit 18A that may be used to implement sensing circuit 16 and interface circuit 18 in system 10 of FIG. 1, in accordance with an embodiment of the disclosure.

FIG. 6 is a block diagram illustrating another example circuit 42 that may be used to implement Hall effect sensor 12 and switching circuits 14A, 14B in example system 10, in accordance with another embodiment of the disclosure.

### DETAILED DESCRIPTION OF ILLUSTRATIVE EMBODIMENT

The present disclosure encompasses Hall effect sensor devices that provide improved sensitivity and allows for electrode rotation, i.e., “spinning” in an asymmetric sense/bias configuration. The Hall effect sensor device includes a semiconductor magnetic field sensing element body integrated on a die, multiple bias electrodes disposed on and in electrical contact with the semiconductor magnetic field sensing element, with at least two bias electrodes corresponding to and disposed on each side of the sensing element body. The Hall effect sensor also includes multiple sensing electrodes separate from the bias electrodes, with at least one sensing conductor corresponding to each side of the sensor body, so that each of the sensing electrodes sense voltage across the semiconductor magnetic field sensing element body and never conduct a bias current.

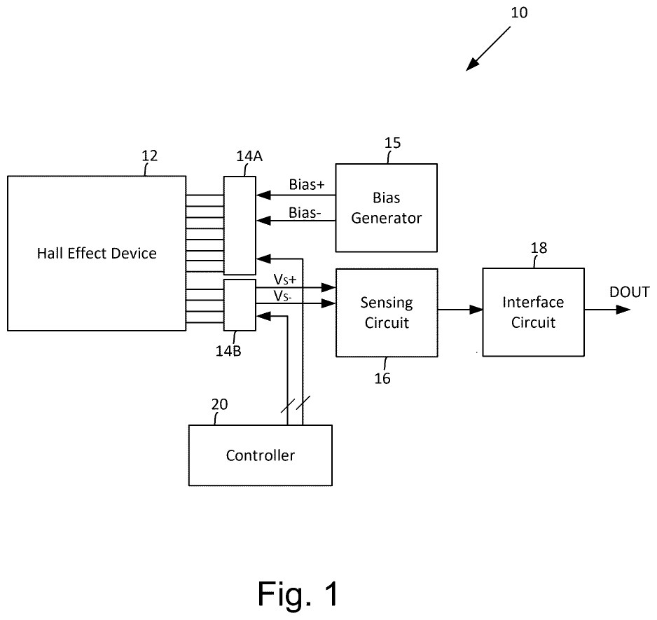

Referring now to FIG. 1, a block diagram illustrating an example system 10 is shown, in accordance with an embodiment of the disclosure. Example system 10 may be integrated on a single substrate forming an integrated circuit (IC), or may be constructed from discrete components. A Hall effect sensor 12 in accordance with an embodiment of the disclosure, is coupled to the remainer of system 10 via switching circuits 14A, 14B. A bias generator 15 provides a source of bias current at outputs Bias+, Bias−, which are provided across one axis (“the bias axis”) of Hall effect sensor 12 through switching circuit 14A, and a sensing circuit 16 is coupled across the orthogonal axis (“the sensing axis”) of Hall effect sensor 14B to receive a differential pair of sense voltages Vs+, Vs−, so that an output voltage due to the Hall effect is detected to measure the presence and/or intensity of a magnetic field present at a face of Hall effect device 12. An interface circuit 18 may provide a digitized output DOUT representing an output of sensing circuit 16. Switching circuits 14A, 14B are controlled by a controller 20 to “spin” Hall effect sensor 12, by changing connections to electrodes at edges of Hall effect sensor 12 to rotate the bias axis and the sensing axis to another pair of axes across the face Hall effect sensor 12, i.e., to a 90 degree or a 270 degree rotation and/or to invert the polarity of the connections to the electrodes, i.e., to a 180 degree rotation and to select between 90 degree and 270 degree rotations. Unlike previous Hall effect sensor implementations, the bias electrodes and sense electrodes, along with their connections, are completely separate, as will be described in further detail below. Therefore, switching circuits 14A, 14B contain distinct switches not sharing any connection to electrodes between them, and none of the electrodes that are coupled to bias generator 15 by switching circuit 14A are ever connected to sensing circuit 16, and similarly none of the electrodes that are coupled to sensing circuit 16 by switching circuit 14B are ever connected to bias generator 16, over all of the above-described rotations.

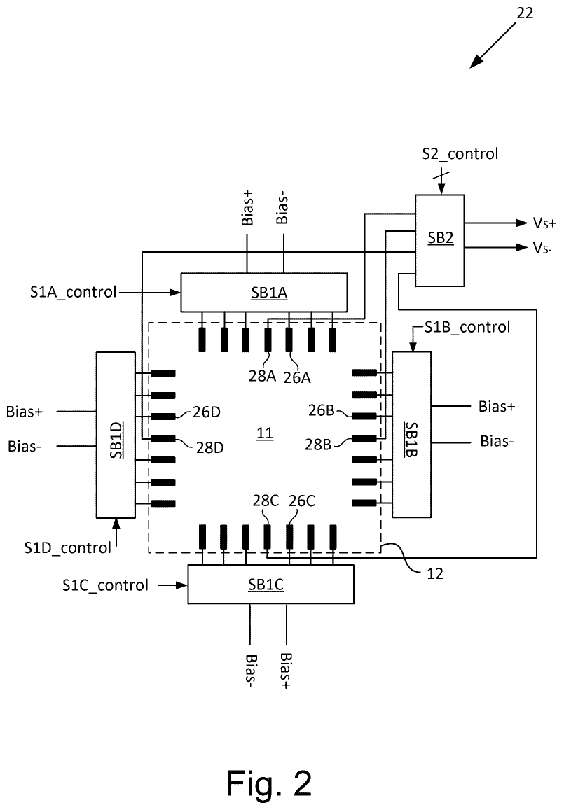

Referring now to FIG. 2, a block diagram illustrating an example circuit 22 that may be used to implement Hall effect sensor 12 and switching circuits 14A, 14B in example system 10 is shown, in accordance with another embodiment of the disclosure. Each side of Hall effect sensor 12 includes seven electrodes, which are generally thin metal stubs extending from the edges of a top face of a body 11 of Hall effect sensor 12, which may be formed as an N-well of lightly doped material formed atop or within an IC substrate. An outer six of the electrodes on each side are used exclusively to produce bias current flow across body 11 and the remaining center electrode is used exclusively for obtaining a sensor output voltage across the orthogonal axis of the top face of body 11. Switching circuit 14A in system 10 of FIG. 1 may be implemented by a plurality of bias switching blocks SB1A, SB1B, SB1C, and SB1D, one for each side, and which are used to select between the two pairs of opposing sides and the two different polarities to deliver bias generator outputs Bias+, Bias−, to bias electrodes 26 of the selected pair of opposing sides of Hall effect sensor 12. In accordance with some embodiments of the disclosure, a further selection between the bias electrodes 26A-26D on one or both of the selected sides may be made, to control a magnitude of the generated bias current, and/or to alter the geometry of the applied bias. While six bias electrodes are illustrated on each side, other numbers of bias electrodes may be implemented, including a single bias electrode that avoids the region of sense electrode(s) 28A-28D, which may also be provided as multiple electrodes rather than single electrodes. In general, the use of narrow bias electrodes 26A-26D minimizes the reduction of sense voltage caused by the presence of the metal areas of bias electrodes 26A-26D, which will provide a lower resistance conduction path across their widths, and the use of a single narrow sense electrode 28A-28D on each side minimizes distortion of the flow of bias current on body 11 of Hall effect sensor 12. Differential pair of sense voltages Vs+, Vs−, are selected as pairs of sense electrodes 28A, 28C and 28B, 28D by a sense voltage switching block SB2, which may implement switching circuit 14B in system 10 of FIG. 1.

A plurality of control signals S1A_control, S1B_control, S1C_control, and S1D_control, control switches within switching blocks SB1A, SB1B, SB1C, and SB1D, respectively, and may be used to spin Hall effect sensor 12 by rotating the position and polarity of application of bias generator outputs Bias+, Bias−, to bias electrodes 26A-26D. Another set of control signals S2_control control switches within sense voltage switching block SB2 to rotate the position and polarity of the selection of differential pair of sense voltages Vs+, Vs−, across the sides of Hall effect sensor 12 that are orthogonal to the sides that receive generator outputs Bias+, Bias−, at their corresponding bias electrodes 26A-26D. Table I below provides an example control pattern for selection of bias electrodes 26A-26D, in which the values for control signals S1A_control, S1B_control, S1C_control, and S1D_control correspond to 00 for no bias, 01 for application of generator output Bias+ to a corresponding one of bias electrodes 26A, 26B, 26C, or 26D and 10 for application of generator output Bias− to the corresponding bias electrode 26A, 26B, 26C, or 26D, in their various rotations as shown in Table I.

TABLE I

| | | | | | Bias+ | Bias− |
|---|---|---|---|---|---|---|
| | | | | | +bias | −bias |
| Rotation | S1A_control | S1B_control | S1C_control | S1D_control | electrode | electrode |
| 0 deg | 00 | 01 | 00 | 10 | 26B | 26D |
| 90 deg | 10 | 00 | 01 | 00 | 26C | 26A |
| 180 deg | 00 | 10 | 00 | 01 | 26D | 26B |
| 270 deg | 01 | 00 | 10 | 00 | 26A | 26C |

Table II provided below provides an example control pattern for selection of sense electrodes 28A-28D by switching block SB2. The binary value of control signal S2_control corresponds to selection (and polarity of selection) of sense electrodes 28A, 28B, 28C and 28D to provide the differential output voltage differential pair of sense voltages Vs+, Vs−, in the various rotations:

TABLE II

| | | sense voltage Vs+ | sense voltage Vs− |
|---|---|---|---|
| Rotation | S2_control | +sense electrode | −sense electrode |
| 0 deg | 00 | 28A | 28C |
| 90 deg | 01 | 28B | 28D |
| 180 deg | 10 | 28C | 28A |
| 270 deg | 11 | 28D | 28B |

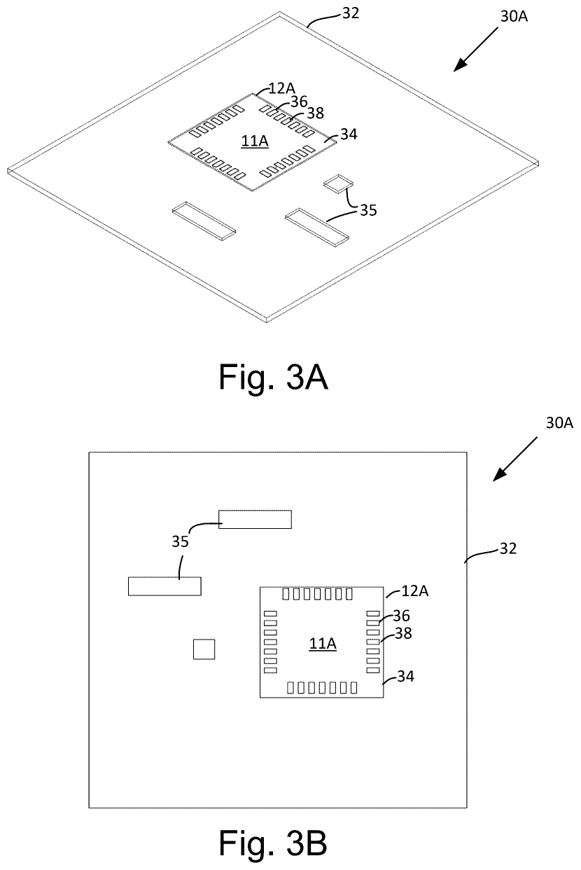

Referring now to FIG. 3A and FIG. 3B, a perspective view, and a top view, respectively, of an example IC 30A that may be used to implement system 10 of FIG. 1 is shown, in accordance with an embodiment of the disclosure. IC 30A includes a substrate 32 in or on which a body 11A of a Hall effect sensor 12A is formed, either by formation of an N-well as described above, but which alternatively may be a deposited material of suitable semiconductor characteristics, such as Gallium Arsenide (GaAs), with sense electrodes 38 and bias electrodes 36 formed atop body 11A on each side. Other circuits 35 may also be formed on substrate 32 and interconnected with Hall effect sensor 12A, including, for example, switching circuits 14A, 14B, controller 20, bias generator 15, sensing circuit 16, and interface circuit 18, forming a system-on-chip (SoC) implementation of system 10 of FIG. 1, and which may include a larger system incorporating system 10 of FIG. 1 as a Hall effect measurement sub-system.

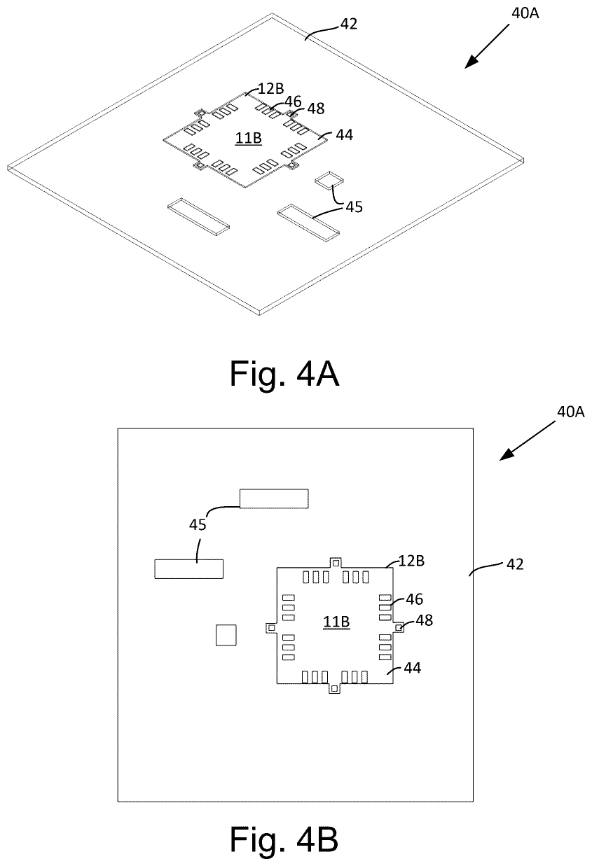

Referring now to FIG. 4A and FIG. 4B, a perspective view, and a top view, respectively, of another example IC 40A that may be used to implement system 10 of FIG. 1 is shown, in accordance with an embodiment of the disclosure. IC 40A is similar to IC 30A of FIGS. 3A-3B, so only differences between them will be described below. IC 40A includes a substrate 42 in or on which a body 11B of a Hall effect sensor 12B is, with sense electrodes 48 and bias electrodes 46 provided on each side. In Hall effect sensor 12B, extensions of body 11B are provided, to locate sense electrodes 48 away from the area of bias electrodes 46, and further reduce distortion of the flow of bias current across body 11B of a Hall effect sensor 12B and improve the magnetic field measurement sensitivity of Hall effect sensor 12B. Other circuits 45 may also be formed on substrate 42 and interconnected with Hall effect sensor 12B.

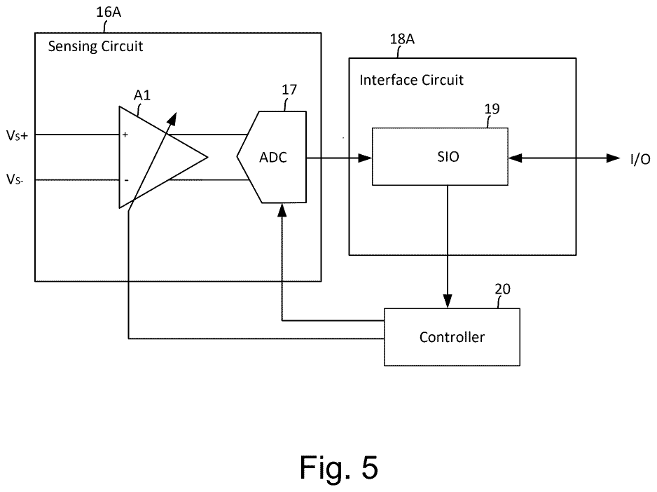

Referring now to FIG. 5, a simplified schematic diagram showing details of an example sensing circuit 16A and interface circuit 18A that may be respectively used to implement sensing circuit 16 and interface circuit 18 in system 10 of FIG. 1 is shown, in accordance with an embodiment of the disclosure. Example sensing circuit 16A includes a programmable gain amplifier (PGA) A1, illustrated in fully-differential form, and that provides a differential input to an analog-to-digital converter (ADC) 17. PGA A1 and ADC 17 are controlled by controller 20, which in turn may be controlled through interface circuit 18A, which in the illustrative example, is implemented by a serial input/output (SIO) circuit 19. A serial interface I/O provides interconnection to external circuits that control and consume measurements/detections of magnetic fields performed by system 10 of FIG. 1.

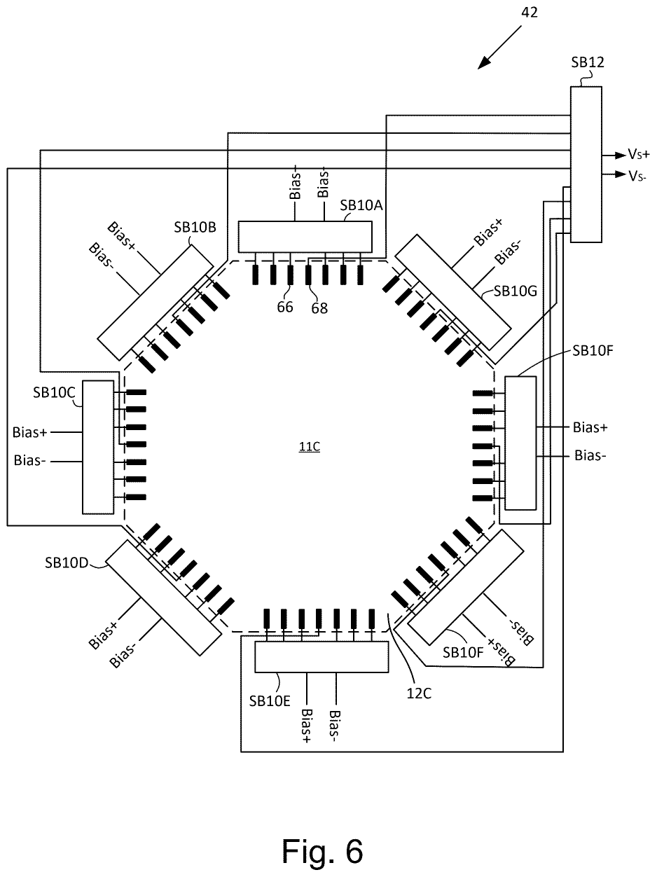

Referring now to FIG. 6, a block diagram illustrating another example circuit 42 that may be used to implement Hall effect sensor 12 and switching circuits 14A, 14B in example system 10 is shown, in accordance with another embodiment of the disclosure. Example circuit 42 is similar to example circuit 22 of FIG. 2, so only differences between them will be described below. Body 11C of a Hall effect sensor 12C has eight sides, which is provided for an illustration of a Hall effect sensor having more than four sides, but other even numbers of sides may alternatively be included, in accordance with other embodiments of the disclosure. Additionally, the shape of the sides of the Hall effect sensor may be curved, piecewise linear, or another shape not defining a regular polygon, in which case the Hall effect sensor body may be circular, or otherwise having an area not defined by straight, orthogonal lines. Switching circuit 14A in system 10 of FIG. 1 may be implemented by a plurality of bias switching blocks SB10A-SB10G, one for each side, and which are used to select between two pairs of opposing sides and the two different polarities to deliver bias generator outputs Bias+, Bias−, to bias electrodes 66 of the selected pair of opposing sides of Hall effect sensor 12C. Sense electrode 68 on each side minimizes distortion of the flow of bias current on body 11 of Hall effect sensor 12. Differential pair of sense voltages Vs+, Vs−, are selected as pairs of sense electrodes 68 by a sense voltage switching block SB12, which may implement switching circuit 14B in system 10 of FIG. 1.

In summary, this disclosure shows and describes Hall effect sensors, integrated circuits incorporating the Hall effect sensors, and their methods of operation/construction. The Hall effect sensor devices may include a semiconductor magnetic field sensing element body integrated on a die and having at least four sides, a plurality of bias electrodes disposed on and in electrical contact with the semiconductor magnetic field sensing element, the plurality of bias electrodes comprising at least two bias electrodes corresponding to and disposed on each side, and a plurality of sensing electrodes separate from the bias electrodes and comprising at least one sensing conductor corresponding to each side. Each of the sensing electrodes sense voltage across the semiconductor magnetic field sensing element body and may never conduct a bias current.

In some example embodiments, the sensors may further include a first plurality of switching circuits, one corresponding to each side and coupled to the at least two bias electrodes of the corresponding side, and a control circuit coupled to the switching circuit that activates pairs of the first plurality of switching circuits to selectively apply a bias current or voltage across a corresponding pair of opposing ones of the sides. The pairs of opposing ones of the sides may be sequentially activated to rotate a direction of applied current across a face of the semiconductor magnetic field element body. In some example embodiments, the sensors may include a bias circuit coupled to the first plurality of switching circuits for providing the bias current or voltage, and a second plurality of switching circuits, one corresponding to each side and coupled to the at least one sensing conductor of the corresponding side. The second plurality of switching circuits may be coupled to the control circuit to sequentially select pairs of the at least one sensing electrodes of opposing sides, and each of the at least one sensing electrodes may never be never coupled to the bias circuit. In some example embodiments, a number of bias electrodes selected by the first plurality of switching circuits for each rotation may be made selectable to control a magnitude of the applied current.

In some example embodiments, the Hall effect sensor devices may include a sensing circuit coupled to the second plurality of switching circuits for generating an output from the voltage sensed by selected pairs of the plurality of sensing electrodes, and the sensing circuit may never be coupled to any of the plurality of bias electrodes. In some example embodiments, the semiconductor magnetic field sensing element body may have an extension projecting on each side, and the second plurality of sensing electrodes may be disposed on the extension of their corresponding side. In some example embodiments, the semiconductor magnetic field sensing element body may be formed from N-type semiconductor material. In some example embodiments the number of sides may be four sides. In other example embodiments, the number of sides may be an even number greater than four.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to other types of sensor circuits other than Hall effect sensors.

What is claimed is:

1. A Hall effect sensor device, comprising:
a semiconductor magnetic field sensing element body integrated on a die and having at least four sides;
a plurality of bias electrodes disposed on and in electrical contact with the semiconductor magnetic field sensing element, the plurality of bias electrodes comprising at least two bias electrodes corresponding to and disposed on each side; and
a plurality of sensing electrodes separate from the bias electrodes and comprising at least one sensing conductor corresponding to each side, wherein each of the sensing electrodes sense voltage across the semiconductor magnetic field sensing element body and never conduct a bias current.

2. The Hall effect sensor device of claim 1, further comprising:
a first plurality of switching circuits, one corresponding to each side and coupled to the at least two bias electrodes of the corresponding side; and
a control circuit coupled to the switching circuit that activates pairs of the first plurality of switching circuits to selectively apply a bias current or voltage across a corresponding pair of opposing ones of the sides, wherein the pairs of opposing ones of the sides are sequentially activated to rotate a direction of applied current across a face of the semiconductor magnetic field element body.

3. The Hall effect sensor device of claim 2, further comprising:
a bias circuit coupled to the first plurality of switching circuits for providing the bias current or voltage; and
a second plurality of switching circuits, one corresponding to each side and coupled to the at least one sensing conductor of the corresponding side, wherein the second plurality of switching circuits is coupled to the control circuit to sequentially select pairs of the at least one sensing electrodes of opposing sides, wherein each of the at least one sensing electrodes is never coupled to the bias circuit.

4. The Hall effect sensor device of claim 3, wherein a number of bias electrodes selected by the first plurality of switching circuits for each rotation is selectable to control a magnitude of the applied current.

5. The Hall effect sensor device of claim 3, further comprising a sensing circuit coupled to the second plurality of switching circuits for generating an output from the voltage sensed by selected pairs of the plurality of sensing electrodes, and wherein the sensing circuit is never coupled to any of the plurality of bias electrodes.

6. The Hall effect sensor device of claim 1, wherein the semiconductor magnetic field sensing element body has an extension projecting on each side, and wherein the second plurality of sensing electrodes are disposed on the extension of their corresponding side.

7. The Hall effect sensor device of claim 1, wherein the semiconductor magnetic field sensing element body is formed from N-type semiconductor material.

8. The Hall effect sensor device of claim 1, wherein the at least four sides consists of four sides.

9. The Hall effect sensor device of claim 1, wherein the at least four sides consists of a number of sides greater than four.

10. A system for sensing a magnetic field and integrated on a semiconductor die, the system comprising:
a Hall effect sensor device that includes a semiconductor magnetic field sensing element body integrated on a die and having at least four sides, a plurality of bias electrodes disposed on and in electrical contact with the semiconductor magnetic field sensing element, the plurality of bias electrodes comprising at least two bias electrodes corresponding to and disposed on each side, a plurality of sensing electrodes separate from the bias electrodes and comprising at least one sensing conductor corresponding to each side, a first plurality of switching circuits, one corresponding to each side and coupled to the at least two bias electrodes of the corresponding side, and a second plurality of switching circuits, one corresponding to each side and coupled to the at least one sensing conductor of the corresponding side, wherein the second plurality of switching circuits is coupled to the control circuit to sequentially select pairs of the at least one sensing electrodes of opposing sides, wherein each of the at least one sensing electrodes is never coupled to the bias circuit;
a control circuit coupled to the switching circuit that activates pairs of the first plurality of switching circuits to selectively apply a bias current or voltage across a corresponding pair of opposing ones of the sides, wherein the pairs of opposing ones of the sides are sequentially activated to rotate a direction of applied current across a face of the semiconductor magnetic field element body;
a bias circuit coupled to the first plurality of switching circuits for providing the bias current or voltage;
a sensing circuit coupled to the second plurality of switching circuits for generating an output from a voltage sensed by selected pairs of the plurality of sensing electrodes, wherein the sensing circuit is never coupled to any of the plurality of bias electrodes;
an analog-to-digital converter having an input coupled to the sensing circuit for converting the voltage to a digital value; and
a digital interface having an input coupled to the analog-to-digital converter for providing a digital output indicative of the digital value.

11. The system of claim 10, wherein the semiconductor magnetic field sensing element body has an extension projecting on each side, and wherein the second plurality of sensing electrodes are disposed on the extension of their corresponding side.

12. A method of sensing a magnetic field, comprising:
providing a semiconductor magnetic field sensing element body integrated on a die and having at least four sides;
coupling the semiconductor magnetic field sensing element body to a bias source with a plurality of bias electrodes disposed on and in electrical contact with the semiconductor magnetic field sensing element, the plurality of bias electrodes comprising at least two bias electrodes corresponding to and disposed on each side; and
coupling the semiconductor magnetic field sensing element body to a sensing circuit with a plurality of sensing electrodes separate from the bias electrodes and comprising at least one sensing conductor corresponding to each side, wherein each of the sensing electrodes sense voltage across the semiconductor magnetic field sensing element body and never conduct a bias current.

13. The method of claim 12, further comprising:
connecting and disconnecting the semiconductor magnetic field sensing element body to the bias source with a first plurality of switching circuits, one corresponding to each side and coupled to the at least two bias electrodes of the corresponding side; and
activating pairs of the first plurality of switching circuits to selectively apply a bias current or voltage across a corresponding pair of opposing ones of the sides, wherein the pairs of opposing ones of the sides are sequentially activated to rotate a direction of applied current across a face of the semiconductor magnetic field element body.

14. The method of claim 13, sequentially selecting pairs of the at least one sensing electrodes of opposing sides with a second plurality of switching circuits, one corresponding to each side and coupled to the at least one sensing conductor of the corresponding side, wherein the second plurality of switching circuits, and wherein each of the at least one sensing electrodes never coupled to the bias circuit.

15. The method of claim 14, further comprising selecting a number of bias electrodes by the first plurality of switching circuits for each rotation to control a magnitude of the applied current.

16. The method of claim 14, further comprising a sensing circuit coupled to the second plurality of switching circuits for generating an output from a voltage sensed by selected pairs of the plurality of sensing electrodes, and wherein the sensing circuit is never coupled to any of the plurality of bias electrodes.

17. The method of claim 12, wherein the semiconductor magnetic field sensing element body has an extension projecting on each side, and wherein the second plurality of sensing electrodes are disposed on the extension of their corresponding side.

18. The method claim 12, wherein the semiconductor magnetic field sensing element body is formed from N-type semiconductor material.

19. The method of claim 12, wherein the at least four sides consists of four sides.

20. The method of claim 12, wherein the at least four sides consists of an even number of sides greater than four.
